(19) United States
(12) Patent Application Publication
(10) Pub. No.: US 2020/0227515 A1
(43) Pub. Date: Jul. 16, 2020

(54) Bismuth-Doped Ferroelectric Devices

(71) Applicant: Arm Limited, Cambridge (GB)

(72) Inventors: Lucian Shifren, San Jose, CA (US); Carlos Alberto Paz de Araujo, Colorado Springs, CO (US); Jolanta Bozena Celinska, Colorado Springs, CO (US); Saurabh Vinayak Suryavanshi, Mountain View, CA (US)

(21) Appl. No.: 16/248,496

(22) Filed: Jan. 15, 2019

(51) Int. Cl. H01L 49/02; H01L 27/11502; H01L 29/78

(52) U.S. Cl. CPC H01L 28/56; H01L 29/78391; H01L 27/11502

(57) ABSTRACT

Briefly, embodiments of claimed subject matter relate to devices and methods for formation of ferroelectric materials utilizing transition metals, transition metal oxides, post transition metals, and/or post transition metal oxides, which may be doped with bismuth (Bi) in a concentration of between about 0.001% to about 25.0%. Alternatively, a dopant may include bismuth oxide (Bi₂O₃) or may include bismuth aluminum oxide ((BiₓAl₁₋ₓ)₂O₃). In particular embodiments, such utilization of bismuth and/or related dopants may bring about stabilization of relatively thin ferroelectric devices.

### TECHNICAL FIELD

This disclosure relates to circuits and methods for fabricating and/or utilizing ferroelectric materials to form electronic devices.

### BACKGROUND

In a computing device, which may include devices such as general-purpose hand-held computers, gaming devices, communications devices, smart phones, embedded or special-purpose computing systems, memory devices may be utilized to store instructions, for example, for use by one or more processors of the computing device. Such computing devices may utilize various memory technologies, such as random-access memory (RAM), to store instructions executable by a processor and/or to store any results of such execution. In such memory devices, a binary logic value of “1,” or a binary logic value of “0,” may be determined at a bit line of a RAM cell in response to a voltage being applied to the gate of one or more access transistors of a cell of a RAM.

Other types of memory that may be utilized in computing devices may include, for example, ferroelectric memories, in which polarization of a ferroelectric material may be utilized to store a binary logic value of “1” or a binary logic value of “0.” To bring about storage of binary logic values, a memory cell that includes a ferroelectric material may be polarized in a first orientation, which may give rise to storage of a first binary logic value, while polarization of the ferroelectric material in a second orientation may bring about storage of a second binary logic value.

However, for at least some memory applications, as well as applications involving sensors that utilize ferroelectric capacitors, certain ferroelectric materials may be subject to instability. Such instability may be especially evident when utilizing sensors of reduced dimensions, such as sensors comprising one or more submicron dimensions. In addition, over time, performance of certain ferroelectric materials may begin to degrade. Such degradation may be exhibited as loss of remanent polarization and/or other figures-of-merit of ferroelectric devices. Thus, although the technology of ferroelectric devices continues to advance, instability and/or lack of endurance of ferroelectric devices, particularly as such devices continue to be reduced in size, may limit the magnitude of such advances. For these reasons, and others, stabilization of ferroelectric materials continues to be an active area of investigation.

### BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, or apparatuses described herein.

FIG. 1A is a block diagram of a ferroelectric capacitor and a graph of device polarization as a function of an applied voltage according to various embodiments;

FIG. 1B is a block diagram of a ferroelectric capacitor having a relatively low figure-of-merit and a graph of device polarization as a function of an applied voltage according to various embodiments;

FIG. 2 shows a circuit that includes a ferroelectric material, positioned between a conductive substrate and a conductive overlay, and coupled to a gate portion of a field-effect-transistor, according to an embodiment;

FIG. 3A is a diagram of a representative lattice structure of an unstable/partial ferroelectric material;

FIG. 3B is a diagram of a hafnium zirconium lattice structure doped with bismuth to exhibit ferroelectric behavior according to an embodiment;

FIG. 4A is a graph showing stress versus strain of a material according to an embodiment;

FIG. 4B is a representative isotropic material showing in-plane strain according to an embodiment;

FIG. 4C is a graph showing polarization as a function of dopant concentration according to an embodiment;

FIG. 4D is a graph showing a rate of change of polarization as a function of dopant concentration according to an embodiment;

FIG. 4E is a graph showing a normalized voltage pulse utilized to determine switching time of a ferroelectric device according to an embodiment;

FIG. 4F is a schematic diagram showing a circuit up used to derive a switching time of a ferroelectric device according to an embodiment;

FIG. 4G is a graph showing an approach toward measuring a switching time of a ferroelectric device according to an embodiment;

FIG. 4H is a graph showing polarization saturation and remanent polarization of a ferroelectric device according to an embodiment;

FIG. 4I is a graph showing capacitance of a device as a function of an applied voltage according to an embodiment;

FIG. 4J is a graph showing device polarization is a function of an applied electric field and localized areas of maximum capacitance according to an embodiment;

FIG. 4K illustrates a graph of

$$\frac{1}{{C}^{2}}$$

for a ferroelectric device according to an embodiment;

FIG. 5A is a graph showing device polarization as a function of an applied voltage and crystallographic plane identifiers associated with a candidate ferroelectric device according to an embodiment;

FIG. 5B is a diagram showing a polycrystalline ferroelectric material between a conductive substrate and a conductive overlay according to an embodiment;

FIG. 5C shows crystallographic plane identifiers of individual crystals of a polycrystalline arrangement of the ferroelectric material of FIG. 5B according to an embodiment; and

FIG. 6 is a flow chart for a method of fabricating bismuth-doped ferroelectric devices according to various embodiments.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

As previously mentioned, in a computing device, such as a general-purpose hand-held computer, a gaming device, or the like, memory devices may be utilized to store instruction for execution by one or more processors of the computing device and/or to store any results of such execution. In such memory devices, a binary logic value of “1,” or a binary logic value of “0,” may be determined at a bit line of a RAM cell in response to a voltage being applied to the gate of one or more access transistors of a bit cell of a RAM. A particular type of RAM, which may utilize ferroelectric materials, may be polarized along a first orientation to bring about storage of a first binary logic value. Polarizing a ferroelectric material along a second axis, such as an axis oriented in a direction opposite to the first axis, may bring about storage of a second binary logic value. Polarization of ferroelectric memory cells may be controlled, for example, via applying a voltage to the memory cell to change (e.g., to reverse) a polarization state of the memory cell.

Accordingly, it may be appreciated that it may be beneficial for polarization voltages to correspond to voltages that are already present, for example, in a memory controller of the computing device. Otherwise, a memory controller of the computing device may require a separate voltage source, which may increase complexity of a ferroelectric-based memory system. To bring about switching of a polarization state of a ferroelectric memory cell in response to applying an available voltage, it may be desirable to limit a thickness dimension of a film used to form a ferroelectric memory cell. By way of limiting a thickness dimension (t) of a ferroelectric memory cell, an electric field (Eₚ) having sufficient magnitude may be generated so as to polarize the ferroelectric memory cell without exceeding an available voltage (V). This may be summarized substantially in accordance with expression (1) below:

V=t·Eₚ (1)

Expression (1) indicates that a voltage required to generate an electric field (E_{P}) of a magnitude sufficient to polarize a ferroelectric memory cell is directly proportional to a thickness dimension (t) of the ferroelectric film. Accordingly, it may be appreciated that for ferroelectric films having increased thickness (t), a proportionally-increased voltage may be utilized to bring about polarization switching of the ferroelectric film. Such voltages may be greater than a voltage available on a controller, for example, utilized to perform read and write operations to/from ferroelectric memory devices.

For other types of ferroelectric devices, such as imaging sensors utilizing ferroelectric materials, for example, an ability to decrease thickness (t) of a ferroelectric memory cell may bring about an increase in sensitivity. In one example, a ferroelectric-based imaging sensor, which utilizes measurement of a capacitance to determine presence of received signal, may benefit from a ferroelectric memory cell of a decreasing thickness (t), substantially in accordance with expression (2), below:

C=εₒA/t (2)

wherein expression (2) indicates that, for a given area (A), capacitance (C) may be increased by way of decreasing thickness between electrodes of the capacitor.

In computer memory applications and/or sensor applications, ferroelectric memory cells may experience fatigue over device lifetimes. For example, in at least some types of ferroelectric devices, noticeable degradation in device polarization as a function of an applied voltage may occur after, perhaps, 100,000 polarization reversals in connection with storage of binary digital values. In other instances, remanent polarization of a ferroelectric device may begin to degrade, which may affect ability of a memory controller to determine a polarization state of a memory material. Such degradation may bring about an increased number of memory write errors, decreased sensor sensitivity, and/or may bring about other undesirable effects.

Accordingly, particular embodiments of claimed subject matter provide a stabilizing dopant for ferroelectric materials comprising at least 75.0%, for example, of hafnium oxide or hafnium zirconium oxide. In particular embodiments of claimed subject matter, a ferroelectric material may comprise transition metal oxides or transition metal compounds other than hafnium oxide and hafnium zirconium oxide, such as transition metal oxides or transition metal compounds comprising a significant percentage, such as at least 75.0%, of scandium (Sc), titanium (Ti), vanadium (V), chromium (Cr), manganese (Mn), iron (Fe), cobalt (Co), nickel (Ni), copper (Cu), zinc (Zn), yttrium (Y), niobium (Nb), molybdenum (Mo), technetium (Tc), ruthenium (Ru), rhodium (Rh), palladium (Pd), silver (Ag), cadmium (Cd), tantalum (Ta), tungsten (W), rhenium (Re), osmium (Os), iridium (Ir), platinum (Pt), gold (Au), mercury (Hg), rutherfordium (Rf), dubnium (Db), seaborgium (Sg), bohrium (Bh), hassium (Hs), meitnerium (Mt), darmstadtium (Ds), roentgenium (Rg), copernicium (Cn), or any combination thereof. In addition, claimed subject matter may provide a stabilizing dopant for post transition metal oxides or post transition metal compounds and post transition metal oxides, such as gallium (Ga), indium (In), tin (Sn), thalium (Tl), lead (Pb), or any combination thereof.

Thus, particular embodiments of claimed subject matter may utilize the above-identified transition metal oxides and post transition metal oxides, which may utilize a bismuth dopant, such as an oxide of bismuth, (e.g., Bi₂O₃), or bismuth aluminum oxide (e.g., (BiₓAl₁₋ₓ)₂O₃, wherein 0.01<x<0.99). Before discussing various embodiments in reference to the accompanying figures, a brief description of various nonlimiting embodiments is provided in the following paragraphs. In particular embodiments, ferroelectric memory cells comprising HfO₂ or HfZrO₂ may be designed with bismuth or a bismuth-containing compound to yield stability and to reduce fatigue such as in connection with repeated read and write memory operations.

For example, particular embodiments may be directed to a device, having a conductive substrate and one or more layers of ferroelectric material formed over the conductive substrate. The one or more layers of the ferroelectric material may be formed from a transition metal oxide, or a post transition metal oxide, having a concentration of at least about 75.0%. The one or more layers of the ferroelectric material may include a dopant species of bismuth in a concentration of between about 0.001% to about 25.0%. In one embodiment, the dopant species of bismuth may include Bi₂O₃ in a concentration of 0.001% to about 25.0%, or may include (BiₓAl₁₋ₓ)₂O₃, wherein 0.01<x<0.99, in a concentration of about 0.001% to about 25.0%. In one embodiment, the concentration of the bismuth dopant species may induce a chemical strain to achieve between 50.0% and 100.0% of a theoretical maximum polarization of the c-axis orthorhombic phase as computed from the polarization of HfₓZr₍₁₋ₓ)O₂, wherein 0.01<x<0.99, in the ferroelectric material. In an embodiment, the one or more layers of the ferroelectric material may comprise a thickness of between 2.0 nm and about 30.0 nm. In one embodiment, the above-described device may be configured to operate as a two-terminal device. In one embodiment, the above-described device may be configured to operate as a three-terminal device.

In one embodiment, the one or more layers of ferroelectric material of the above-described device may be formed from a transition metal oxide, wherein the transition metal oxide includes (HfO₂) or includes hafnium zirconium oxide (HfₓZr₍₁₋ₓ₎O₂, wherein 0.01<x<0.99). In one embodiment, one or more layers of the ferroelectric material of the above-described device may include a dopant species of Bi₂O₃ or (BiₓAl₁₋ₓ)₂O₃, wherein 0.01<x<0.99. In particular embodiments, the above-described device may further comprise a conductive overlay positioned over the one or more layers of the ferroelectric material, in which at least one of the conductive substrate and the conductive overlay include a concentration of at least 50.0% tantalum nitride. In one embodiment, the concentration of the bismuth dopant species may induce chemical strain to achieve between 50.0% and 100.0% of a theoretical maximum polarization of the c-axis orthorhombic phase as computed from polarization of HfₓZr₍₁₋ₓ₎O₂, wherein 0.01<x<0.99, in the ferroelectric material. In an embodiment, the above-described device may further comprise a conductive overlay positioned over the one or more layers of the ferroelectric material, wherein at least one of the conductive substrate and the conductive overlay include a concentration of at least 50.0% titanium nitride (TiN). In an embodiment, the above-described device may further comprise a conductive overlay positioned over the one or more layers of the ferroelectric material, wherein at least one of the conductive substrate and the conductive overlay include a concentration of at least 50.0% tantalum nitride (TaN). In an embodiment, the above-described device may further comprise a conductive overlay positioned over the one or more layers of the ferroelectric material, wherein at least one of the conductive substrate and the conductive overlay include a concentration of at least 50.0% platinum (Pt).

Various embodiments may be directed to a device, having a conductive substrate and one or more layers of ferroelectric material formed over the conductive substrate. In such a device, the one or more layers of ferroelectric material may be formed from a material having a chemical formula of AₓB₍₁₋ₓ₎Bi_{(y)}(L)_{2+δ}:L′, wherein A and B correspond to transition metals or post transition metals, and wherein L corresponds to oxygen (O), sulfur (S), selenium (Se), or tellurium (Te), and wherein L′ may correspond to molecular oxygen (O₂), iodine (I), bromine (Br), sulfur S, thiocyanate (SCN), chlorine (Cl), azide (N₃), trifluoride (F₃), cyanate (NCO), hydroxide (OH), ethylene (C₂H₄), water (H₂O), NCS (N-bonded), acetonitrile CH₃CN, glycine, pyridine, ammonia (NH₃), ethylene diamine, 2,2′bipyridine, phen(1,10-phenanthroline), nitrogen dioxide (NO₂), PPh₃ (triphenylphosphine), cyanide (CN), or carbon monoxide (CO). In the chemical formula AₓB₍₁₋ₓ₎Bi_{(y)}(L)_{2+δ}:L′, y=⅔δ. In particular embodiments, y is equal to a function of x, where x is the solid-solution stoichiometry parameter of the dominant phase (e.g., the ratio Hf/Zr).

The above-described device may comprise a conductive overlay positioned over the one or more layers of the ferroelectric material, wherein at least one of the conductive substrate and the conductive overlay include a concentration of at least 50.0% TaN, at least 50.0% TiN, or at least 50.0% Pt. In one embodiment, one or more layers of a ferroelectric material of the above-described device may comprise a thickness of between about 2.0 nm and about 30.0 nm. In one embodiment, the above-described device may be coupled to a gate portion of a field-effect transistor, wherein a polarization state of the device is configured to control at least a portion of a channel region of the field-effect transistor. The one or more layers of the ferroelectric material of the above-described device may be deposited during a back-end-of-line process, wherein ferroelectricity is conveyed to a gate portion of the field-effect transistor by way of a via.

Various embodiments may be directed to a method including forming, in a chamber, a conductive substrate and forming, over the conductive substrate, one or more layers of a ferroelectric material. The one or more layers of the ferroelectric material may be formed from a transition metal oxide, or a post transition metal oxide, having a concentration of at least about 75.0%. The one or more layers of the ferroelectric material may include a dopant species of bismuth in a concentration of between about 0.001% to about 25.0%. The above-described method may further include forming a conductive overlay on the one or more layers of ferroelectric material, in which at least one of the conductive substrate and the conductive overlay are formed from a material that includes at least 50.0% TaN, at least 50.0% TiN, or at least 50.0% Pt.

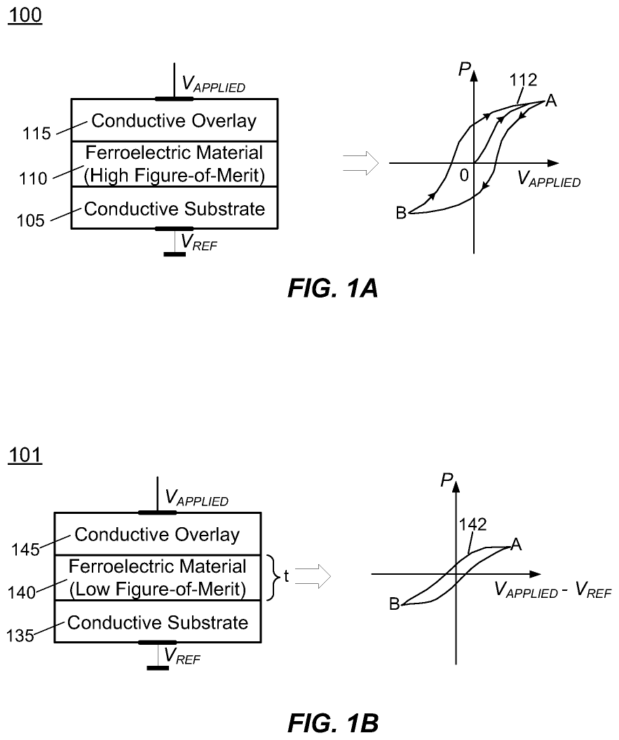

Particular embodiments will now be described with reference to the figures, such as FIG. 1, which is a diagram 100 of a ferroelectric capacitor and a graph of device polarization as a function of an applied voltage according to various embodiments. The arrangement of ferroelectric material 110 between conductive substrate 105 and conductive overlay 115 may correspond to a two-terminal ferroelectric capacitor structure exhibiting polarization hysteresis. Thus, in operation, as an applied voltage (V_{APPLIED}), with respect to a reference voltage (V_{REF}), comprises a positive value, polarization of ferroelectric material may begin to increase until saturation point A is achieved. Saturation point A may correspond to a point at which an increase in applied voltage (V_{APPLIED}) does not result in significant increase in polarization of ferroelectric material 110. Responsive to reaching saturation point A, residual (or remanent) polarization may be maintained even after the applied voltage (V_{APPLIED}) decreases to a value of 0.0 V. Also as shown in FIG. 1A, responsive to an applied voltage (V_{APPLIED}) comprising an increasingly negative value, ferroelectric material 110 may be polarized in a substantially opposite orientation, until saturation point B is achieved. Saturation point B may correspond to a point at which an increasingly negative applied voltage (V_{APPLIED}) does not result in a significant increase in oppositely-directed polarization of ferroelectric material 110. In response to an applied voltage (V_{APPLIED}) approaching 0.0 V, ferroelectric material 110 may exhibit residual (or remanent) polarization.

In the device of FIG. 1A, a ferroelectric device may exhibit a relatively high figure-of-merit by way of utilizing a transition metal oxide, or a post transition metal oxide, such as previously described herein, and by utilizing a dopant species of bismuth having a concentration of between about 0.001% to about 25.0%. In one embodiment, the bismuth dopant species may include Bi₂O₃ in a concentration of 0.001% to about 25.0% or may include (BiₓAl₁₋ₓ)₂O₃, wherein 0.01<x<0.99, also in a concentration of about 0.001% to about 25.0%. With respect to FIG. 1, it may be appreciated that when a transition metal oxide or post transition metal oxide are doped with a bismuth species, an applied voltage may operate to “coerce” ferroelectric material 110 to exhibit polarization. Such polarization may exhibit relatively high saturation points, such as depicted at points A and B in the graph of FIG. 1A. Additionally, over repeated changes in polarization (e.g., between positive and negative polarizations) ferroelectric material 110 may continue to exhibit relatively high saturation points. Further, when an applied voltage (V_{APPLIED}) is reduced, or removed entirely, ferroelectric material 110 may exhibit consistently high values of residual (or remanent) polarization.

In various embodiments, ferroelectric material 110 may comprise any transition metal oxide or any post transition metal oxide. In one aspect, ferroelectric material 110 may include one or more layers doped with bismuth and/or bismuth-containing substitutional ligands so as to form a material having a chemical formula of AₓB₍₁₋ₓ₎Bi_{(y)}(L)_{2+δ}:L′, wherein A and B correspond to transition metals or post transition metals, and wherein L corresponds to oxygen (O), sulfur (S), selenium (Se), or tellurium (Te), and wherein L′ may correspond to molecular oxygen (O₂), iodine (I), bromine (Br), sulfur S, thiocyanate (SCN), chlorine (Cl), azide (N₃), trifluoride (F₃), cyanate (NCO), hydroxide (OH), ethylene (C₂H₄), water (H₂O), NCS (N-bonded), acetonitrile CH₃CN, glycine, pyridine, ammonia (NH₃), ethylene diamine, 2,2′bipyridine, phen(1,10-phenanthroline), nitrogen dioxide (NO₂), PPh₃ (triphenylphosphine), cyanide (CN), or carbon monoxide (CO) and others. In the chemical formula AₓB₍₁₋ₓ₎Bi_{(y)}(L)_{2+δ}:L′, y=⅔δ. In particular embodiments, y is equal to a function of x, where x is the solid-solution stoichiometry parameter of the dominant phase (e.g., the ratio Hf/Zr).

Ferroelectric material 110 may comprise bismuth or bismuth-containing dopant in a concentration (e.g., an atomic or molecular concentration) of between about 0.001% and about 25.0%. In particular embodiments, atomic concentrations of a bismuth dopant species, such as is Bi₂O₃ or (BiₓAl₁₋ₓ)₂O₃ (wherein 0.01<x<0.99), may comprise a more limited range of or molecular concentrations such as, for example, between approximately 1.0% and 10.0%. However, claimed subject matter is not necessarily limited to the above-identified dopants and/or concentrations. It should be noted that claimed subject matter is intended to embrace ferroelectric materials comprising any concentration of dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, or the like, utilized in fabrication of ferroelectric devices from transition metal oxide or post transition metal oxide materials.

In particular embodiments, formed ferroelectric materials may be strain-quenched via rapid thermal annealing comprising exposure of a formed ferroelectric material to a temperature range of between about 375.0° C. to about 475.0° C. for a duration of between 5.0 and 15.0 seconds. In one particular embodiment, strain-quenching may comprise rapid thermal annealing of a ferroelectric material via exposure of the ferroelectric material to an elevated temperature, such as a temperature within range of between about 400.0° C. to about 450.0° C. for a duration of about 10.0 seconds. Strain-quenching may be performed in a chamber utilizing a pressure, for example, of between 1.0 atm and 10.0 atm utilizing an ambient nitrogen environment. Such strain-quenching may operate to control (e.g., to reduce) vacancies within the lattice of a ferroelectric material. In embodiments, a formed ferroelectric material may be exposed to an additional annealing process, such as utilizing a chamber, via exposure to an oxygen environment for a duration of between about 5.0 seconds and about 10.0 seconds at an elevated temperature of about 300.0° C. to about 450.0° C. In particular embodiments, such additional annealing may take place before or after forming a top electrode, such as a conductive overlay, which may be deposited on or over one or more layers of a ferroelectric material. Annealing may comprise an optimized process, in which variables of temperature, duration, and pressure may be adjusted so as to activate strain fields while permitting distribution of bismuth, for example, within grain boundaries of a polycrystalline ferroelectric material.

FIG. 1B is a block diagram of a ferroelectric capacitor having a relatively low figure-of-merit and a graph of device polarization as a function of an applied voltage according to various embodiments. In diagram 101, ferroelectric material 140 has been disposed between conductive overlay 145 and conductive substrate 135. However, as shown in FIG. 1B, ferroelectric material 140 may exhibit a figure-of-merit much lower than the figure-of-merit of ferroelectric material 110 (FIG. 1A). Accordingly, the graph of device polarization shown in FIG. 1B indicates a much smaller hysteresis than exhibited by hysteresis graph 112 of FIG. 1A. Thus, hysteresis graph 142 of FIG. 1B may exhibit much lower polarization saturation, such as indicated by points “A” and “B,” on hysteresis graph 142. Further, hysteresis graph 142 may exhibit much lower residual or remanent polarization than hysteresis graph 112. Further, ferroelectric material 140 of FIG. 1B may degrade at a much faster rate than ferroelectric material 110 of FIG. 1A. Thus, 140 may fall short of performance expectations for memory devices and/or other types of devices.

It should be noted that although hysteresis graph 142 of FIG. 1B has been shown and described as comprising a particular shape as a result of a relatively low figure-of-merit of ferroelectric material 140, in particular instances, a relatively low figure-of-merit of a ferroelectric material may give rise to differently-shaped hysteresis graphs. Thus, in certain implementations, hysteresis graphs corresponding to ferroelectric materials having a relatively low figures-of-merit may exhibit even less remanent electric field polarization, even lower polarization saturation, etc., and claimed subject matter is not limited in this respect.

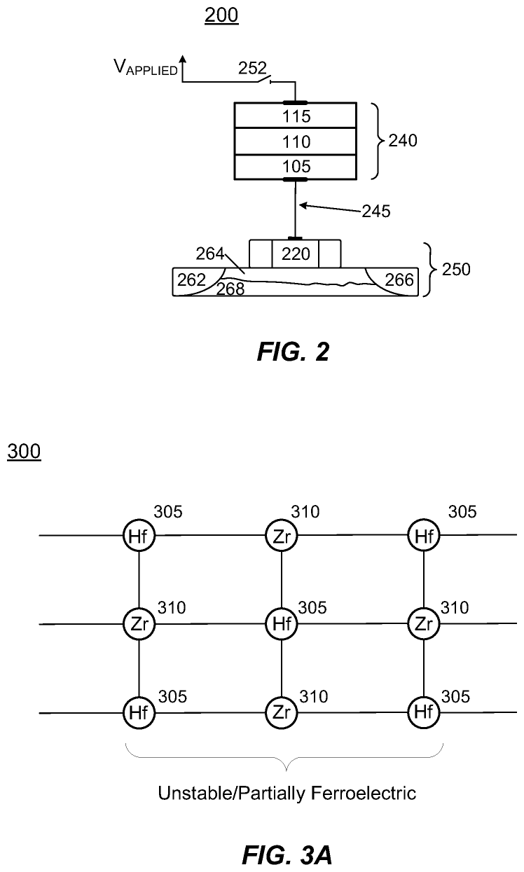

FIG. 2 shows a circuit 200 that includes a ferroelectric material, positioned between a conductive substrate and a conductive overlay, and coupled to a gate portion of a field-effect-transistor, according to an embodiment. It may be appreciated that the two-terminal device of FIG. 2 may be similar in construction to the device of FIG. 1A. In the embodiment of FIG. 2, conductive overlay 115, ferroelectric material 110, and conductive substrate 105 may cooperate to control gate portion 220 of a field-effect transistor, such as field-effect transistor 250. Thus, in the embodiment of FIG. 2, responsive to an applied voltage (V_{APPLIED}), such as in response to closure of switch 252, ferroelectric material 110 may attain polarization saturation (e.g. point A of hysteresis graph 112 of FIG. 1A). Also in response to an applied voltage across ferroelectric material 210, gate portion 220 of field-effect transistor 250 may about formation of, for example, depletion region 264, which may control conduction of electrons, for example, through channel 268.

In addition, after attaining such polarization saturation, when switch 252 is opened, residual (or remanent) polarization of ferroelectric material 210 may continue to exert control over the width of depletion region 264 of field-effect transistor 250. Thus, it may be appreciated that, as shown in FIG. 2, after a voltage signal is removed from the ferroelectric material 110, residual (or remanent) polarization may continue to affect conduction of current between the drain 262 and source 266 of field-effect transistor 250. It may also be appreciated that field-effect transistor 250 is constructed during a front-end-of-line fabrication process and that device 240 may be constructed during a back-end-line fabrication process. Between front-end and back-end processes, conductive via 245 may be formed so as to couple conductive substrate of device 240 to gate portion 220 of field-effect transistor 250. Thus, in accordance with the example depicted in FIG. 2, a ferroelectric material having a relatively high figure-of-merit may be utilized to control a width of the depletion channel region for a transistor or other type of device fabricated during a front-end-of-line process.

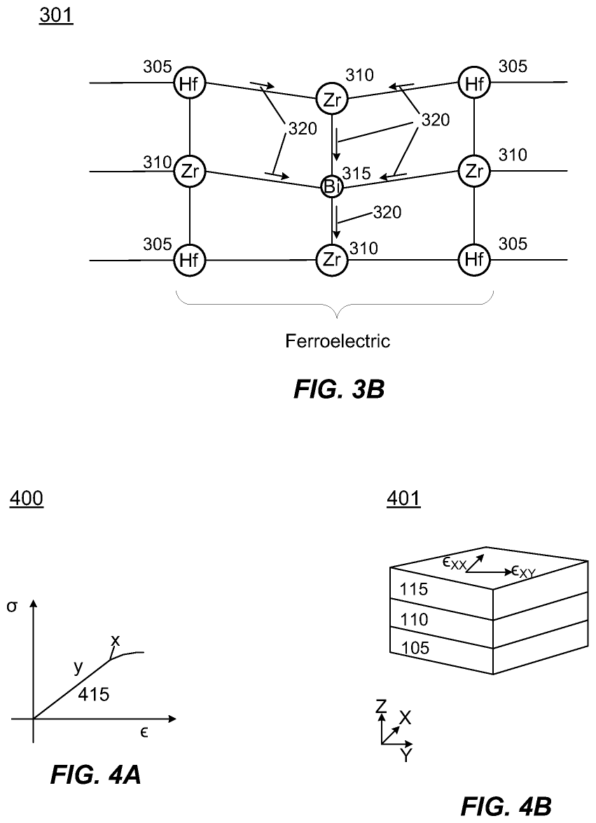

FIG. 3A is a diagram of a representative lattice structure of an unstable/partial ferroelectric material. As shown in diagram 300, an unstable/partial ferroelectric material may comprise a lattice, which may comprise atoms, such as atoms 305 and 310 that represent atoms of a transition metal or a post transition metal, throughout an individual crystal of a polycrystalline lattice structure of the material. It may be appreciated that the representative lattice structure of diagram 300 depicts an orderly and un-strained arrangement of atoms and shared electron orbitals. Such orderly and un-strained arrangement of atoms and shared orbitals of may be brought about responsive to atomic radii of Hf, having an atomic radius of approximately 208.0 pm, and Zr, having an atomic radius of approximately 206.0 pm, being comparable to each other. Thus, in view of the un-strained arrangement of atoms and shared orbitals of Hf and Zr atoms, substantial ferroelectricity may not be expected to be exhibited by the polycrystalline structure of FIG. 3A. It should be noted that in the particular embodiment of FIG. 3, Hf and Zr atoms are shown as being present in approximately equal proportions, however claimed subject matter is intended to embrace materials comprising a wide variety of transition metals oxides and post transition metal oxides.

FIG. 3B is a diagram 301 of a Hf—Zr lattice structure doped with bismuth to exhibit ferroelectric behavior according to an embodiment. In the embodiment of diagram 301, bismuth atom 315 has been situated within the lattice. In particular embodiments, bismuth atom 315, which comprises an atomic radius of 143.0 pm may be significantly smaller than the atomic radius of Hf and Zr (208.0 pm and 206.0 pm, respectively), may give rise to distortion in the lattice. Accordingly, as shown in diagram 301, presence of the significantly smaller bismuth atom may bring about strain in horizontal and vertical directions, as depicted by arrows 320. It is contemplated that such strain in the polycrystalline lattice structure of a transition metal oxide or post transition metal oxide may be instrumental in the formation ferroelectric materials having a relatively high figure-of-merit. It should be noted that dopant species other than bismuth may be utilized, and claimed subject matter is not limited in this respect. In particular embodiments, doping a transition metal oxide or post transition metal oxide may be realized via doping a HfO₂ material or a HfₓZr₍₁₋ₓ₎O₂ material (wherein 0.01<x<0.99) with Bi₂O₃ or (BiₓAl₁₋ₓ)₂O₃, wherein 0.01<x<0.99. This may give rise to a ferroelectric material comprising at least 75.0% transition metal oxide or post transition metal oxide and between 0.001% and 25.0% bismuth or bismuth-containing dopant.

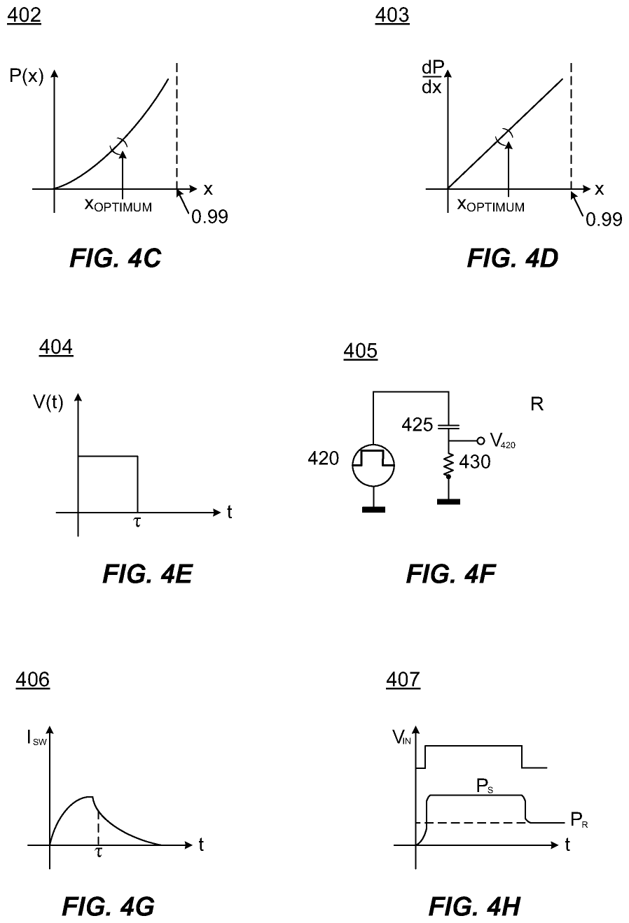

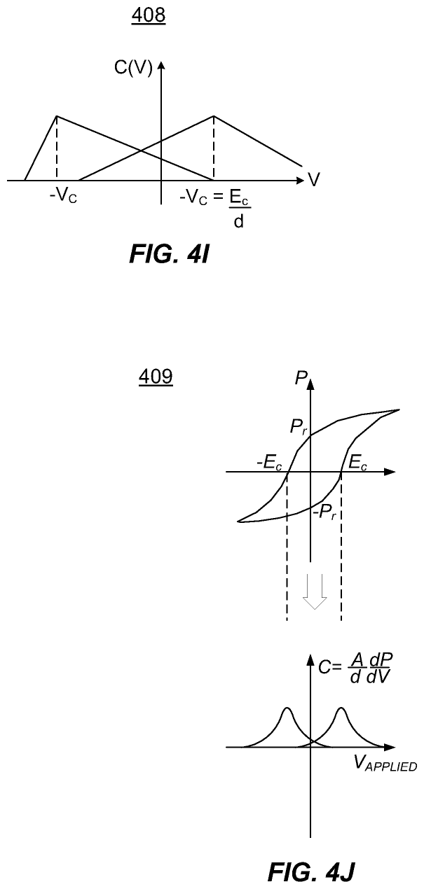

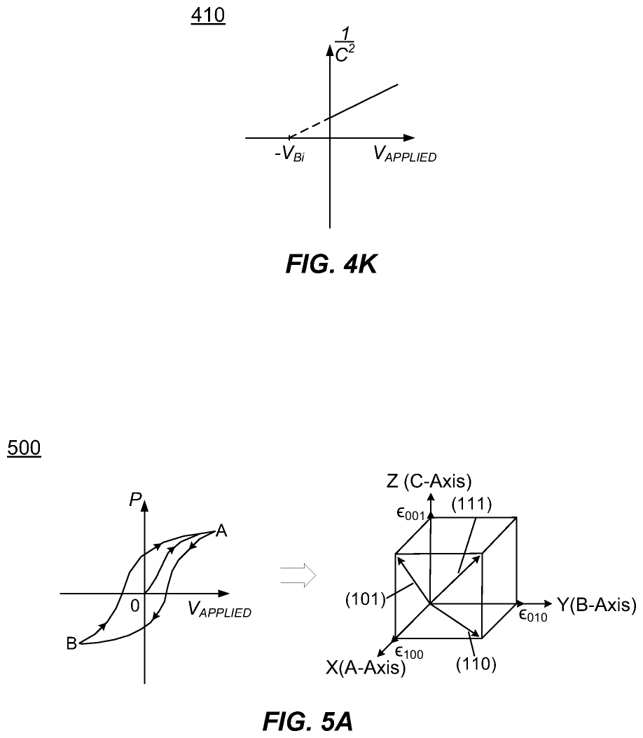

It may be appreciated that stress versus strain relationships that bring about ferroelectric properties in materials comprising transition metal oxides and post transition metal oxides, such as described with reference to FIG. 3B, may be further described with reference to FIG. 4A, which shows a stress versus strain graph 415 for isotropic elastic materials, according to an embodiment. As shown in graph 400, the slope (y) of the linear region represents σ/ϵ, which may be known as Young's modulus, or the elastic modulus of a material. Point “X” on graph 450 indicates a point at which a material may begin to deform responsive to increased strain. However, for purposes of forming materials in which lattice strain introduces ferroelectric effects, it may be advantageous to retain strain by way of structuring and/or arranging materials. Accordingly, in particular embodiments, strain may be introduced by way of material selection of a conductive substrate, such as conductive substrate 105 of FIG. 1A, as well as selection of the conductive overlay, such as conductive overlay 115 of FIG. 1B. It is contemplated that in particular embodiments, to bring about a level of strain in a representative lattice, one or more of a conductive overlay and a conductive substrate may comprise at least 50.0% tantalum nitride (TaN), at least 50.0% titanium nitride (TiN), or at least 50.0% platinum (Pt). It is contemplated that in certain embodiments, a conductive overlay or a conductive substrate comprising such materials operate to provide strain, which may bring about a desired level of ferroelectric behavior.

To illustrate stress/strain relations that bring about ferroelectric behavior, FIG. 4B is a diagram 401 illustrating a representative material to show in-plane and out-of-plane strain. With FIG. 4B in mind, in-plane strain may be expressed substantially in accordance with expression (3), below:

$${∈}_{XX} = {∈}_{Y Y} = \frac{{a}_{11} - {a}_{0}}{{a}_{0}} \qquad ( 3 )$$

wherein in expression (3) the quantity α₁₁ comprises parallel displacement after strain, and wherein α₀ comprises original lattice spacing without strain. Also with FIG. 4B in mind, out-of-plane strain may be expressed substantially in accordance with expression (4) below:

$${∈}_{ZZ} = \frac{{a}_{⊥} - {a}_{0}}{{a}_{0}} \qquad ( 4 )$$

wherein expression (4) introduces α_{⊥} to denote perpendicular displacement after strain.

As previously discussed herein, HfO₂ among other transition metal oxides, such as HfₓZr₍₁₋ₓ₎O₂ (wherein 0.01<x<0.99) may be doped with bismuth (or a bismuth-containing molecule) give rise to a dopant concentration of between about 0.001% and about 25.0%, thereby obtaining in ferroelectric behavior. A model may be developed to relate “x” from the expression HfₓBi₍₁₋ₓ₎O_{2±δ} and HfₓZr₍₁₋ₓ₎Bi_{y}O_{2±δ} with “y” as a function of “x” to express maximum ferroelectric polarization (wherein y=⅔δ). In such a model, “x” may be proportional to the strain at the molecular level, which may be brought about by a dopant, such as bismuth. Such a model may additionally consider coupling of material strain to strain created responsive to one or more of conductive overlay 115 and conductive substrate 105 comprising TiN, TaN, or Pt. Accordingly, in at least particular embodiments of claimed subject matter, a dopant, such as bismuth, or any other atom having a small atomic radius in relation to other atoms of the lattice. A transition metal oxide, such as HfO₂ or HfₓZr₍₁₋ₓ₎O₂ (or a post transition metal oxide) may be selected so as to introduce appropriate strain when bismuth, or other element having a relatively small atomic radius. With this in mind, a polarization expression (P(x)) may be derived to determine polarization with respect to “x” in conjunction with electrode-induced strain (e.g., strain introduced by a conductive overlay/conductive substrate comprising TiN, TaN, or Pt). In certain embodiments, such an addition of a bismuth-containing dopant to an active material, such as active material 110 of FIG. 1A, may be likened to addition of a small amount of impurity, such as silicon dioxide (SiO₂), calcium oxide (CaO), or other impurities, to plane glass so as to control strain to avoid cracks from developing in plane glass.

Accordingly, to optimize a material system to bring about a level of polarization in a ferroelectric material, three quantities, such as bulk modulus (K), Poisson's ratio (μ), and shear stress (γ) are to be evaluated. Bulk modulus may be expressed substantially in accordance with expression (5), below:

$$K = - \frac{d P}{d V} \qquad ( 5 )$$

wherein V=volume,

$$\frac{d P}{d V}$$

corresponds to a change in pressure per unit volume

$$( pressure = \frac{Force}{Area} ) .$$

In this context, stress may operate much in the same way as pressure. In addition, density (ρ) may be expressed substantially in accordance with expression (6), below:

$$K = ρ \frac{d P}{d ρ} \approx ρ \frac{d σ}{d ρ} \qquad ( 6 )$$

wherein σ corresponds to the overall applied to representative material, such as representative material 301 of FIG. 3B. Poisson's ratio may be expressed in a manner that relates bulk modulus (K) and Young's modulus (Y), substantially in accordance with expression (7), below:

$$μ ≅ \frac{1}{2} - \frac{6 Y}{K} \qquad ( 7 )$$

Shear strain may be expressed substantially in accordance with expression (7A), below:

$${γ}_{X Y} \approx \frac{Δ a}{{a}_{0}} \qquad ( 7 A )$$

FIG. 4B shows a material positioned between a conductive substrate and a conductive overlay, according to various embodiments. In FIG. 4B, at least one of conductive overlay 445 and conductive substrate 435 comprises at least 50.0% TiN. For a material undergoing strain, such as a film comprising ferroelectric material 110 of FIG. 1A:

$${ϵ}_{XX} = {ϵ}_{YY} = \frac{{a}_{11} - {a}_{0}}{{a}_{0}} \qquad ( 8 )$$

wherein α₀ corresponds to the lattice constant of active layer 440, and wherein α₁₁ corresponds to in-plane strain the lattice constant for the xy plane shown in FIG. 4A. Thus, contributions of individual dipole moments of individual lattice structures of active material 440 may be summed, substantially in accordance with expression (9), below:

$$P ( x ) = \frac{{Σ}_{i} {μ}_{i}}{V} = q \frac{{Σ}_{i} {a}_{i}}{V} \qquad ( 9 )$$

wherein in expression (9), μᵢ=αᵢ correspond to dipole moments in which:

$${a}_{i} \approx \frac{{a}_{⊥} - {a}_{11}}{2} \qquad ( 10 )$$

Expression 10 can be rewritten substantially in accordance with expression (11), in which:

$$P ( x ) = \frac{q}{v} \frac{1}{2} [ {a}_{11} - {a}_{0} + {a}_{⊥} - {a}_{0} ] \qquad ( 11 )$$

Multiplication of expression (11) by

$$\frac{{a}_{0}}{{a}_{0}}$$

gives rise to

$$P ( x ) = \frac{q}{2 v} {a}_{0} [ \frac{{a}_{11} - {a}_{0}}{{a}_{0}} + \frac{{a}_{⊥} - {a}_{0}}{{a}_{0}} ] \qquad ( 12 )$$

In expression (12) the quantity

$$\frac{{a}_{11} - {a}_{0}}{{a}_{0}}$$

may be recognized as ϵ_{XX}, ϵ_{YY}=ϵ_{PLANE} and the quantity

$$\frac{{a}_{⊥} - {a}_{0}}{{a}_{0}}$$

may be recognized as ϵ_{ZZ}. Thus, expression (12) may be rewritten to form expression (13):

$$P ( x ) = \frac{q}{v} ( \frac{{a}_{0}}{2} ) [ ϵ - {ϵ}_{ZZ} ] \qquad ( 13 )$$

In expression (13), ϵ_{PLANE} may be substituted for ϵ.

From expression (13) it may be noticed that ϵ_{ZZ} is electrode dominant (e.g., at least partially dependent on thickness of a transition metal oxide or post transition metal oxide material) and ϵ_{PLANE} is at least partially dependent on strain introduced by doping of a transition metal oxide or post transition metal oxide. However, both electrode-induced and chemically-induced strain can be combined by way of expression (13). Expression (13) can be rewritten as expression (14):

$$P ( x ) = \frac{q}{v} [ {a}_{11} + {a}_{⊥} - 2 {a}_{0} ] \qquad ( 14 )$$

Multiplying expression (14) by

$$\frac{{a}_{11}}{{a}_{11}}$$

=gives:

$$P ( x ) = \frac{q}{v} [ 1 + \frac{{a}_{⊥}}{{a}_{11}} - \frac{2 {a}_{0}}{{a}_{11}} ] .$$

### Letting

$$1 / ( f ( x ) ) = \frac{{a}_{11}}{{a}_{⊥}} , and 1 / ( {f}_{0} ( x ) ) = \frac{{a}_{0}}{{a}_{11}} ,$$

then

$$f ( x ) = \frac{{a}_{⊥}}{{a}_{11}} and {f}_{0} ( x ) = \frac{{a}_{11}}{{a}_{0}} .$$

Thus expression (15), below, may result:

$$\frac{f ( x )}{{f}_{0} ( x )} = \frac{\frac{{a}_{⊥}}{{a}_{11}}}{\frac{{a}_{11}}{{a}_{0}}} = \frac{{a}_{⊥}}{{a}_{11}} \cdot \frac{{a}_{0}}{{a}_{11}} = \frac{{a}_{⊥} {a}_{0}}{{a}_{11}^{2}} \qquad ( 15 )$$

Wherein expression (15) may be rewritten as expression (16):

$$P ( x ) = \frac{q}{v} {a}_{11} [ 1 + f ( x ) - 2 {f}_{0} ( x ) ] \qquad ( 16 )$$

Taking expression (16) and rewriting results in expression (17):

$$P ( x ) = \frac{q}{v} {a}_{11} {f}_{0} [ \frac{1}{{f}_{0}} + \frac{f ( x )}{{f}_{0}} - 2 ] \qquad ( 17 )$$

### Substituting

$$\frac{f ( x )}{{f}_{0}} = \frac{{a}_{0}}{{a}_{11}} f ( x ) ,$$

brings about expression (18):

$$P ( x ) = \frac{q}{v} ( {a}_{11} + {a}_{0} {f}_{0 ( x )} f ( x ) - 2 ) \qquad ( 18 )$$

Taking the derivative of

$$\frac{d P}{d x} = \frac{q}{v} {a}_{0} \frac{d ( {f}_{0} f )}{d x} = {f}_{0} \frac{d f}{d x} + f \frac{d {f}_{0}}{d x} .$$

### However

$${f}_{0} f = \frac{{a}_{11}}{{a}_{0}} \cdot \frac{{a}_{⊥}}{{a}_{11}} ,$$

then cancelling α₁₁ yields:

$${f}_{0} f = \frac{{a}_{⊥}}{{a}_{0}} or \frac{d P}{d x} = \frac{q}{v} \frac{d {a}_{⊥}}{d x} ,$$

which indicates that the slope of P(x) as a function of x is positive and depends on the out-of-plane strain (α_{⊥}). The out-of-plane strain occurs, at least in part, responsive to the electrode metal, which may comprise at least a substantial portion (e.g., at least 50.0%) of TiN, TaN, or Pt. Thus, considering a lattice with perpendicular compression, this implies that α_{⊥} is proportional to (γ₁R_{DOPANT}−γ_{⊥}R₀), wherein R₀=radius of an Hf atom. Returning to the expression for

$$\frac{d P}{d x} ,$$

the quantity can be rewritten as expression (19) below:

$$\frac{d P}{d x} = \frac{q}{v} {γ}_{E} \frac{d}{d x} [ {γ}_{1} {R}_{B i} - {γ}_{2} {R}_{Hf} ] \\ {γ}_{1} = 1 - x and {γ}_{2} = x \qquad ( 19 )$$

### Thus

$$\frac{d P}{d x}$$

can be rewritten as expression (20):

$$\frac{d P}{d x} = \frac{q}{v} {γ}_{E} \frac{d}{d x} [ ( 1 - X ) {R}_{B i} - X {R}_{H F} ] = \frac{q}{v} {γ}_{E} ( - {R}_{B i} - {R}_{H f} ) \qquad ( 20 )$$

Expression (20) indicates that α_{⊥}=γ_{E}(γ₁R_{Bi}−γ₂R_{HF}). With this in mind,

$$\frac{d P}{d x}$$

can be rewritten as expression (21):

$$\frac{d P}{d x} = \frac{q}{v} {γ}_{E} ( {R}_{B i} + {R}_{H f} ) \qquad ( 21 )$$

Making the substitution

$$\frac{{R}_{B i}}{{R}_{H f}} = 1 - X$$

since

$$\frac{{a}_{⊥}}{{a}_{0}} \text{∼} \frac{{R}_{B i}}{{R}_{H f}} )$$

and letting

$$\frac{d P}{d x} = - \frac{q}{v} {γ}_{E} {R}_{B i} ( \frac{{R}_{B i}}{{R}_{B i}} + \frac{{R}_{H f}}{{R}_{B i}} ) ,$$

this results in expression (22) below:

$$\frac{d P}{d x} = - \frac{q}{v} {γ}_{E} {R}_{B i} ( 1 + \frac{1}{1 - X} ) \qquad ( 22 )$$

Integrating expression (22) from 0 to P, as shown in expression (23) provides:

$${\int }_{0}^{P} d P = - \frac{q}{v} {γ}_{E} {R}_{B i} ( {\int }_{0}^{X} d X + {\int }_{0}^{X} \frac{1}{1 - X} d X ) \qquad ( 23 )$$

Performing the integration of expression (23) provides expression (24):

$$P ( X ) = - \frac{q}{v} {γ}_{E} {R}_{B i} ( ln ( 1 - X ) - X ) \qquad ( 24 )$$

Since x<1, ln(1−x)<0,

$$ln ( 1 - X ) \approx - {Σ}_{n = 1}^{∞} \frac{{X}^{n}}{n} .$$

Thus, expression (24) can be rewritten as:

$$P ( X ) ≅ \frac{q}{v} {γ}_{E} {R}_{B i} ( - {\sum }_{n = 1}^{∞} \frac{{X}^{n}}{n} - X ) \qquad ( 25 )$$

Considering that the electrodes (e.g., conductive overlay 115 and conductive substrate 105) exert a compressive force, γ_{E} comprises a negative value, expression (25) can be rewritten as:

$$P ( X ) ≅ \frac{q}{v} {γ}_{E} {R}_{B i} ( {\sum }_{n = 1}^{∞} \frac{{X}^{n}}{n} - X ) \qquad ( 26 )$$

A quadratic approximation may be made to expression (26), which yields expression (27):

$$P ( X ) ≅ \frac{q}{v} {γ}_{E} {R}_{D O P A N T} ( X + \frac{{X}^{2}}{2} - X ) , which yields \\ P ( X ) = \frac{q}{v} {R}_{D O P A N T} {γ}_{E} \frac{{X}^{2}}{2} \qquad ( 27 )$$

wherein R_{DOPANT} of expression (27) corresponds to the atomic radius of a bismuth atom.

With expression (27) in mind, FIG. 4C is a graph 402 showing polarization (P(x)) as a function of dopant concentration according to an embodiment. FIG. 4D is a graph 403 showing a rate of change of polarization as a function of dopant concentration according to an embodiment. It may be appreciated that x_{OPTIMUM} may be found experimentally and that

$$P ( x , {x}_{O P T} ) = \frac{q}{2 v} {R}_{B i} {γ}_{E} ( {x}_{OPTIMUM}^{2} - x ) .$$

For the embodiment of bismuth-doped HfO₂, to yield a ferroelectric material of HfₓBi₍₁₋ₓ₎O₂, then:

$$P ( X ) = \frac{q}{2 v} {R}_{B i} {γ}_{E} {X}^{2} \qquad ( 27 A )$$

FIG. 4E is a graph 404 showing a normalized voltage pulse utilized to determine switching time of a ferroelectric device according to an embodiment. Using the expression for current density (J), the change in polarization as a function of time may be expressed as

$$J = \frac{d P ( x )}{d t} .$$

This implies that making the substitution for

$$J \frac{I}{A} ,$$

yields expression (28) below:

J=∫₀^{τ}dt≅∫_{-P}_{ₛ}^{P}^{ₛ}dP=2Pₛ (28)

FIG. 4F is a schematic diagram 405 of a test circuit 405 used to derive a switching time of a ferroelectric device according to an embodiment. In the test circuit of FIG. 4F, signal generator 420 may generate a pulse signal similar to the pulse signal illustrated in FIG. 4E. The pulse signal from signal generator 420 may be transmitted through ferroelectric device 425 and through test resistor 430. In the embodiment of FIG. 4F, test resistor 430 may comprise a resistance of approximately 50.0 Ω, which may correspond to the characteristic impedance of the test circuit. As shown in FIG. 4G, a graph 406 may be utilized in an approach toward measuring a switching time of a ferroelectric device according to an embodiment. Responsive to transmission of the pulse signal from signal generator 420 through ferroelectric device 425, voltage V_{R} may be utilized in expression (29) to determine switching time τ in FIG. 4G.

$$τ = \frac{2 A {P}_{s}}{{V}_{420} - {V}_{C} - {V}_{R}} \qquad ( 29 )$$

wherein V₄₂₀ corresponds to the magnitude of the voltage pulse generated by signal generator 420, and wherein V_{C} corresponds to a voltage measured across ferroelectric device 425, and wherein V_{R} corresponds to the voltage measured between resistor 430 and a reference (e.g., ground) of the test circuit of FIG. 4F. Expression (29) may also be expressed in terms of polarization, such as utilizing expression (27), to yield expression (29A):

$$τ = \frac{2 A \frac{q}{2 v} {R}_{B i} {γ}_{E} {X}^{2}}{( {V}_{420} - {V}_{R} ) - {V}_{C} ( X )} \qquad ( 29 A )$$

In another embodiment, the approach of FIG. 4G may be utilized, wherein T may be measured, via an oscilloscope or other instrument, permits observation of a real-time graph of a switching current (I_{SW}) as a function of time (t). In another embodiment, polarization of a ferroelectric device as a function of time may be determined, in accordance with graph 407 of FIG. 4H. In such an embodiment, an input signal V_{IN} may be plotted against measured polarization of ferroelectric device 425, for example. Polarization saturation (P_{S}) as well as residual (or remanent) polarization P_{R} may also be determined via an oscilloscope or similar instrument. The above-identified approaches allow optimization of P(x) as a function of concentration of a dopant species, such as bismuth. Optimization of expression (30) may provide dopant concentration for a desired (e.g., a maximum) polarization:

$${P}_{r} ( X ) = \frac{{ϵ}_{M E A S} {V}_{C - M E A S U R E D} ( x )}{d} = \frac{q}{2 {V}_{O l}} {R}_{D O P A N T} {γ}_{E} {X}^{2} \qquad ( 30 )$$

wherein:

$${ϵ}_{M E A S} = \frac{\frac{q d}{2 {V}_{0 L}} {R}_{D O P A N T} {γ}_{E} {X}^{2}}{{V}_{C - MEASURED} ( X )} \qquad ( 30 A )$$

As shown in FIG. 4I, which is a graph 408 showing capacitance as a function of an applied voltage, it may be appreciated that a measured value of capacitance (C_{MEASURED}(V)) yields higher peak capacitance as a dopant concentration (x) is increased. This may be summarized in expression (31), below:

$$C ( V ) = \frac{{ϵ}_{M E A S} ( V ) A}{d} \qquad ( 31 )$$

Which indicates that a measured value of capacitance may increase as dopant concentration (x) is also increased.

It may thus be appreciated that at least in particular embodiments, maximum polarization (P(x)) may be expressed in expression (32) below:

$$P ( X ) = \frac{{R}_{D O P A N T} {γ}_{E} {X}^{2}}{2 ( {V}_{0 l} )} \qquad ( 32 )$$

wherein, at least in particular embodiments, R_{DOPANT}>R_{Hf} and R_{Zr}. It may also be appreciated that

$$C ( V ) = \frac{q}{2 ( {V}_{ol} )} A {R}_{D O P A N T} {X}^{2} ,$$

and that

$$\frac{d C}{d {γ}_{E}} = \frac{C}{{γ}_{{E}_{0}}} .$$

The latter expression implies that for an electrode, such as either a conductive overlay or a conductive substrate,

$$C = {C}_{0} {e}^{{γ}_{E} \text{/} {γ}_{{E}_{0}}} ,$$

wherein the quantity γ_{E}_{₀} denotes a nominally compressive electrode. Thus, when considering, for example, an electrode comprising at least a substantial percentage (e.g., at least 50.0%) of TiN versus an electrode comprising at least a substantial percentage of platinum (Pt) capacitance may be expressed as expression (33), below:

$$C = {C}_{0} {e}^{{γ}_{E} ( TiN ) \text{/} {γ}_{{E}_{0}} ( Pt )} \qquad ( 33 )$$

Expression (33) implies that

$${γ}_{E ( T i N )} = \frac{1}{γ {E}_{0} ( P t )} ln ( \frac{C}{{C}_{0}} ) ,$$

which provides an optimized equation for electrodes (such as conductive substrate 105 and conductive overlay 115 of FIG. 1A, for example) as well as a methodology for verifying heterogeneous (e.g., conductive overlay constructed of a material different than a material utilized to construct a conductive substrate) versus electrodes constructed comprising identical material (e.g., both conductive overlay and conductive substrate comprising, for example, at least 50.0% TiN).

FIG. 4J is a graph 409 showing device polarization as a function of an applied electric field and localized areas of maximum capacitance according to an embodiment. It may be appreciated that under the influence of an electric field, polarization of a ferroelectric device be reoriented. It may also be appreciated that a particular values of an applied electric field, capacitance of a ferroelectric device varies between localized minimum values and localized maximum values. In view of the expression relating an applied voltage, V, and electric field, E, (V=d·E, in which d corresponds to a distance) capacitance may vary according to the expression

$$C = \frac{A d P}{dd V} .$$

As shown in FIG. 4K, which illustrates a graph 410 of

$$\frac{1}{{C}^{2}}$$

for a ferroelectric device, capacitance may represent a beneficial approach to optimize capacitance of a ferroelectric device since, at an applied voltage substantially equal to 0.0, C_{BI}=C (V_{BI}).

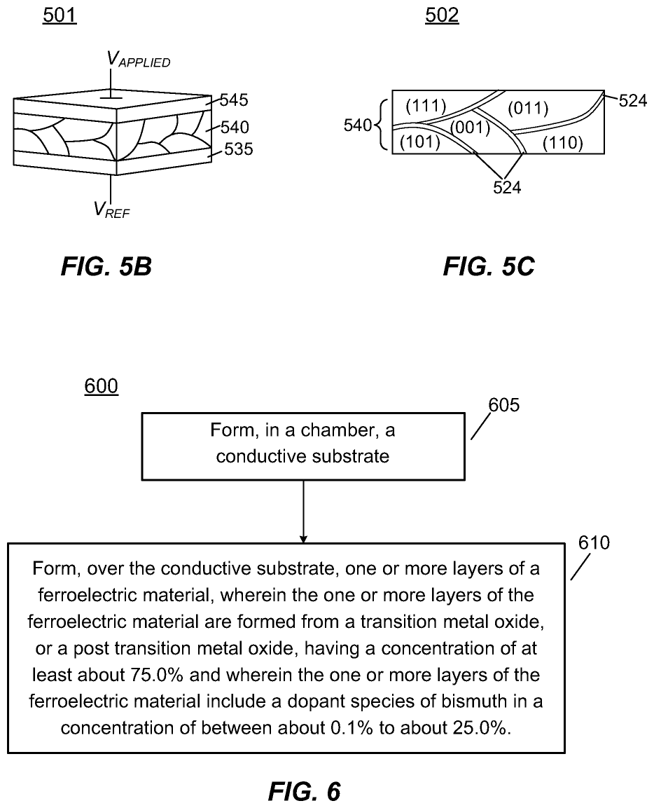

FIG. 5A is a graph 500 showing device polarization as a function of an applied voltage and crystallographic plane identifiers associated with a candidate ferroelectric device according to an embodiment. FIG. 5A indicates that polarization as a function of an applied voltage may be brought about in a polycrystalline ferroelectric device via certain orientations of crystalline structures. Thus, for example, as shown in FIG. 5A, crystalline structures of a polycrystalline ferroelectric device oriented along the 110 plane, the 101, and the 111 planes are contemplated as contributing to ferroelectricity. Crystalline structures of a polycrystalline ferroelectric device oriented in other planes are contemplated as providing only negligible contributions to ferroelectricity. As described in Table I of the article by Min Hyuk Park, Han Joon Kim, Yu Jin Kim, Taehwan Moon, and Cheol Seong Hwang (2014). Titled “The Effects of Crystallographic Orientation and Strain of Thin Hf_{0.5}Zr_{0.5}O₂ Film on Its Ferroelectricity.” Applied Physics Letters, Volume 104, Issue 7, 072901-1 to 072901-5, repeated here for convenience, the strain on the (110), (101), and (111) bring about changes in polarization (P_{⊥}/P_{r,MAX}) of the Hf_{0.5}Zr_{0.5}O₂ material.

TABLE I

| | Plane | Plane | Plane | Plane | Plane |
|---|---|---|---|---|---|
| | (100) | (001) | (110) | (101) | (111) |
| ϵ₁₀₀ | −0.67σ₀/Y | 0.67σ₀/Y | ~0.0 | ~0.0 | 0.33σ₀/Y |
| ϵ₀₁₀ | 0.67σ₀/Y | 0.67σ₀/Y | ~0.0 | 0.67σ₀/Y | 0.33σ₀/Y |
| ϵ₀₀₁ | 0.67σ₀/Y | −0.67σ₀/Y | 0.67σ₀/Y | ~0.0 | 0.33σ₀/Y |
| P_{⊥}/ | 0.0% | 0.0% | 70.7% | 70.7% | 57.7% |
| P_{r,MAX} | | | | | |

Accordingly, Pᵣ provides residual (or remanent) polarization, along a plane that is perpendicular to the surface of the ferroelectric material, such as ferroelectric material 140 of FIG. 1B. It should be noted that in Table I, P_{r,MAX} corresponds to a theoretical maximum polarization along only the c-axis (Z-direction) in a perfect orthorhombic crystal (O-phase). In other embodiments, P_{r,MAX} may correspond to less than a theoretical maximum polarization along the c-axis in a perfect orthorhombic crystal, such as a value of between 50.0% and 100.0% of a theoretical maximum polarization, and claimed subject matter is not limited in this respect.

FIG. 5B is a diagram 501 showing a polycrystalline ferroelectric material between a conductive substrate and conductive overlay according to an embodiment. In diagram 501, ferroelectric material 540 is shown as situated between conductive substrate 535 and conductive overlay 545. Although only a small number of individual crystalline structures of a polycrystalline ferroelectric material are shown in diagram 501, claimed subject matter is intended to embrace any number of individual crystalline structures of a polycrystalline ferroelectric material, virtually without limitation. As shown in the diagram 502 of FIG. 5C, crystallographic plane identifiers of individual crystals of a polycrystalline arrangement of the ferroelectric material of FIG. 5B may be oriented along particular directions. Accordingly, as shown, individual crystals may be oriented along the (111), the (101), the (001), the (011), and the (010) planes. It should be noted that, as described with reference to Table I herein, at least some orientations of individual crystals of a polycrystalline arrangement are capable of contributing to polarization of ferroelectric material. In one embodiment, such orientations correspond to the (101), (110), and the (111) orientations, when the ferroelectric material comprises a predominant amount (e.g., at least 75.0%) of Hf_{0.5}Zr_{0.5}O₂. However, for ferroelectric materials comprising different transition metal oxides or post transition metal oxides, polarization may be brought about via inducing strain along different orientations of crystals of a polycrystalline structure, and claimed subject matter is not limited in this respect. In one example, when a ferroelectric material comprises, HfO₂ it is possible that polarization may be brought about via inducing strain along the (001) orientation of an orthorhombic crystal. Additionally, for transition metal oxides and post transition metal oxides comprising crystalline structures other than orthorhombic, such as simple cubic, body-centered, face-centered, etc. Crystalline structures may further include tetragonal structures (e.g., simple tetragonal, body-centered tetragonal, etc.), as well as monoclinic structures (e.g., simple monoclinic, end-centered monoclinic, etc.), as well as rhombohedral, hexagonal, triclinic, structures, for example, and claimed subject matter is not limited in this respect.

FIG. 5C is an illustration 502 of crystallographic plane identifiers of individual crystals of a polycrystalline arrangement of ferroelectric material of FIG. 5B according to an embodiment. In the embodiment of FIG. 5C, ferroelectric material 540 may correspond to Hf_{0.5}Zr_{0.5}O₂ doped with a bismuth-containing molecule, such as Bi₂O₃, or may comprise bismuth aluminum oxide (BiₓAl₁₋ₓ)₂O₃, in a concentration in the range of about 0.001% to about 25.0%. As previously discussed herein, orientations of individual crystals corresponding to the (101), the (110), and the (111) may contribute to polarization of ferroelectric material 540. However, the individual crystal corresponding to the (001) orientation may be unlikely to contribute to polarization of material 540.

As shown in FIG. 5C, ferroelectric material 540 may comprise grain boundaries 524, which may permit formation of, for example, oxygen vacancies between adjacent crystals. In particular embodiments, such oxygen vacancies may represent dislocations in lattice structure of a crystalline material, which may bring about increases in resistance to the flow of electrons and/or holes through a ferroelectric material. It is contemplated that presence of particular dopant species, such as bismuth, may operate to reduce the presence of oxygen vacancies so as to increase electron and/or hole mobility through the ferroelectric material. In certain embodiments, such “healing” of oxygen vacancies occurs by way of substitution of such vacancies with bismuth and/or bismuth-containing molecules.

FIG. 6 is a flow chart for a method of fabricating bismuth-doped ferroelectric devices according to various embodiments. The method of FIG. 6 may begin at block 605, which may comprise forming, in a chamber, a conductive substrate. In particular embodiments, a conductive substrate may comprise at least 50.0% TiN, TaN, or Pt. The method may continue at block 610 which may comprise forming, over the conductive substrate, one or more layers of ferroelectric material. The one or more layers of the ferroelectric material may be formed from a transition metal oxide, or a post transition metal oxide, having a concentration of at least about 75.0%. The one or more layers of the ferroelectric material may comprise a dopant species of bismuth in a concentration of between about 0.001% to about 25.0%.

Although illustrative embodiments of the invention have been described in detail herein with reference to the accompanying drawings, it is to be understood that the invention is not limited to those precise embodiments, and that various changes, additions and modifications can be effected therein by one skilled in the art without departing from the scope of the invention as defined by the appended claims. For example, various combinations of the features of the dependent claims could be made with the features of the independent claims without departing from the scope of the present invention.

What is claimed is:

1. A device, comprising:
a conductive substrate; and one or more layers of ferroelectric material formed over the conductive substrate, wherein
the one or more layers of ferroelectric material are formed from a transition metal oxide, or a post transition metal oxide, having a concentration of at least about 75.0%, and wherein
the one or more layers of ferroelectric material includes a dopant species of bismuth in a concentration of between about 0.001% to about 25.0%.

2. The device of claim 1, wherein the concentration of the bismuth dopant induces chemical strain to achieve between 50.0% and 100.0% of a theoretical maximum polarization of the c-axis orthorhombic phase as computed from polarization of HfₓZr₍₁₋ₓ₎O₂, wherein 0.01<x<0.99, in the ferroelectric material.

3. The device of claim 1, wherein the one or more layers of the ferroelectric material comprise a thickness of between about 2.0 nanometer and about 30.0 nanometer.

4. The device of claim 1, wherein the device is configured to operate as a two-terminal device.

5. The device of claim 1, wherein the device is configured to operate as a three-terminal device.

6. The device in claim 1 where the dopant species is Bi₂O₃ or (BiₓAl₁₋ₓ)₂O₃, wherein 0.01<x<0.99.

7. The device of claim 1, wherein the one or more layers of ferroelectric material are formed from a transition metal oxide, and wherein the transition metal oxide comprises (HfO₂) or hafnium zirconium oxide (HfₓZr₍₁₋ₓ₎O₂) wherein 0.01<x<0.99.

8. The device in claim 7, wherein the dopant species is Bi₂O₃ or (BiₓAl₁₋ₓ)₂O₃.

9. The device of claim 8, further comprising a conductive overlay positioned over the one or more layers of the ferroelectric material, wherein at least one of the conductive substrate and the conductive overlay include a concentration of at least 50.0% tantalum nitride (TaN).

10. The device of claim 8, wherein the concentration of the bismuth dopant species induces chemical strain to achieve between 50.0% and 100.0% of a theoretical maximum polarization of the c-axis orthorhombic phase as computed from polarization of HfₓZr₍₁₋ₓ₎O₂, wherein 0.01<x<0.99, in the ferroelectric material.

11. The device of claim 10, further comprising a conductive overlay positioned over the one or more layers of the ferroelectric material, wherein at least one of the conductive substrate and the conductive overlay include a concentration of at least 50.0% titanium nitride (TiN).

12. The device of claim 10, further comprising a conductive overlay positioned over the one or more layers of the ferroelectric material, wherein at least one of the conductive substrate and the conductive overlay include a concentration of at least 50.0% of tantalum nitride (TaN).

13. The device of claim 10, further comprising a conductive overlay positioned over the one or more layers of the ferroelectric material, wherein at least one of the conductive substrate and the conductive overlay include a concentration of at least 50.0% platinum (Pt).

14. A device, comprising:
a conductive substrate; and
one or more layers of ferroelectric material formed over the conductive substrate, wherein
the one or more layers of ferroelectric material are formed from a material having a chemical formula of AₓB₍₁₋ₓ₎Bi_{(y)}(L)_{2+δ}:L′, wherein A and B correspond to transition metals or post transition metals, and wherein L corresponds to oxygen (O), sulfur (S), selenium (Se), or tellurium (Te), and wherein L′ may correspond to molecular oxygen (O₂), iodine (I), bromine (Br), sulfur S, thiocyanate (SCN), chlorine (Cl), azide (N₃), trifluoride (F₃), cyanate (NCO), hydroxide (OH), ethylene (C₂H₄), water (H₂O), NCS (N-bonded), acetonitrile CH₃CN, glycine, pyridine, ammonia (NH₃), ethylene diamine, 2,2′bipyridine, phen(1,10-phenanthroline), nitrogen dioxide (NO₂), PPh₃ (triphenylphosphine), cyanide (CN), or carbon monoxide (CO), and wherein y=⅔δ.

15. The device of claim 14, further comprising a conductive overlay positioned over the one or more layers of the ferroelectric material, wherein at least one of the conductive substrate and the conductive overlay include a concentration of at least 50.0% titanium nitride (TiN), at least 50.0% tantalum nitride (TaN), or at least 50.0% platinum (Pt).

16. The device of claim 14, wherein the one or more layers of ferroelectric material comprises a thickness of between about 2.0 nm and about 30.0 nm.

17. The device of claim 14, wherein the device is coupled to a gate portion of a field-effect transistor, and wherein a polarization state of the device is configured to control at least a portion of a channel region of the field-effect transistor.

18. The device of claim 17, wherein the one or more layers of ferroelectric material are deposited during a back-end-of-line process, and wherein ferroelectricity is conveyed to a gate portion of the field-effect transistor by way of a via.

19. A method, comprising:
forming, in a chamber, a conductive substrate; and
forming, over the conductive substrate, one or more layers of a ferroelectric material, wherein
the one or more layers of the ferroelectric material are formed from a transition metal oxide, or a post transition metal oxide, having a concentration of at least about 75.0%, and wherein
the one or more layers of the ferroelectric material include a dopant species of bismuth (Bi) in a concentration of between about 0.001% to about 25.0%.

20. The method of claim 19, further comprising forming a conductive overlay on the one or more layers of the ferroelectric material, wherein at least one of the conductive substrate and the conductive overlay are formed from a material that includes at least 50.0% titanium nitride (TiN), at least 50.0% tantalum nitride (TaN), or at least 50.0% platinum (Pt).

21. The method of claim 19, further comprising annealing the one or more layers of the ferroelectric material in accordance with a process which optimizes chamber temperature, duration, and pressure.
